(19) United States
(12) Patent Application Publication
(10) Pub. No.: US 2003/0100170 A1
(43) Pub. Date: May 29, 2003

(54) Fast diffusion recipe for silicon by NO complexes

(75) Inventors: Wen-Luh Yang, Taichung (TW); Don-Gey Liu, Taichung (TW); Tsong-Jen Yang, Taichung (TW); Giin-Shan Chen, Taichung (TW); Kuo Wei Chu, Taichung (TW)

Correspondence Address: TROXELL LAW OFFICE PLLC, Suite 1404, 5205 Leesburg Pike, Falls Church, VA, 22041, US

(73) Assignee: Feng-Chia University

(21) Appl. No.: 09/995,717

(22) Filed: Nov. 29, 2001

(51) Int. Cl. H01L 21/425; H01L 21/31

(52) U.S. Cl. 438/530; 438/769

(57) ABSTRACT

The present invention relates to a fast diffusion recipe for making silicon by NO complexes, which can quicken impurities diffusion by NO complexes, thus reducing effectiveness for a given period of time and cost of production. When it is used to make CMOS well, processing period would be more rapidly. Because of the produced interface depth is affected by ventilation at stage of heat treatment, and obtaining deeper depth by N₂O compared with using traditional N₂, it is thus clear that this recipe features application and use value.

### FIELD OF THE INVENTION

The present invention is referred to fast diffusion recipe in making integrated circuit, which can improve efficiency and output, extra voids produce within silicon semiconductor by NO complexes, which can quicken impurities diffusing, thus reducing effectiveness for a given period of time and cost of production.

### BACKGROUND OF THE INVENTION

Mixing impurities in the depths of semiconductor with silicon well is done in high temperature furnace at atmosphere of N₂ and O₂, the traditional heat diffusion only can make impurities diffusion at high temperature of N₂ and O₂, then using oxidizing process to strengthen diffusing effect at atmosphere of O₂ OED effect. Voids produce during oxidizing of silicon atom lattices, although achieving the goal, it is a great deal that calls for improving speed.

### PURPOSE OF THE INVENTION

The purpose of the invention is to take same long time for heat treatment but 8 times the interface depths obtained by fast diffusion recipe. Another purpose is to provide CMOS well process with low cost; The third purpose is to change environment for fast diffusion by N₂O, thus saving both time and cost meanwhile no influence to the integrated circuit.

### BRIEF DESCRIPTION OF THE DRAWINGS

The concrete samples of the invention are detailed coordinating the sketches, of which:

FIG. 1 is a sketch of diffusing process by N₂O

FIG. 2 is a sketch of impurities distribution after diffusion at atmosphere of N₂O, O₂ and N₂,

FIG. 3 is a sketch of N₂O flow affecting impurities diffusion;

FIG. 4 shows that it can produce SiN₂O to use N₂O in silicon semiconductor;

FIG. 5 shows high reliable experiment data of the element metal obtained from heat treatment process at atmosphere of N₂O;

FIG. 6 shows experiment data of no obvious worsening to current leakage as N₂O used.

### DETAILED DESCRIPTION OF THE EMBODIMENTS

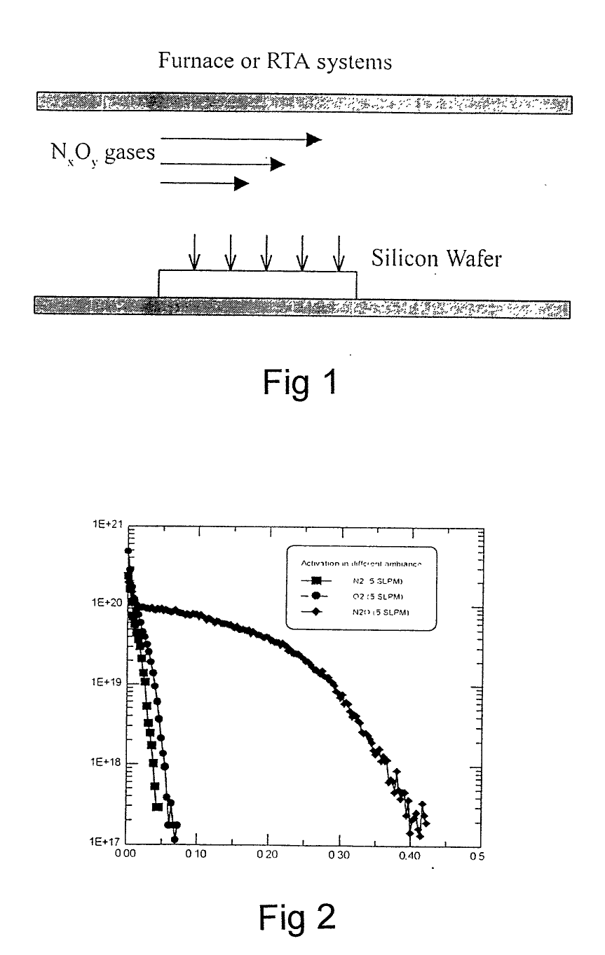

The present invention relates to a recipe of diffusion in processing silicon ( see FIG. 1 ), because of Si atoms can produce great quantity of voids during oxidation in heat treatment process at atmosphere of NO complexes, and compact SiN₂O forms on surface of the semiconductor, which can make voids diffuse towards the base, thus making other impurities fast diffuse by the aid of voids ( see FIG. 2 ) then efficiency of the invention is realized. Both tube-furnace and fast tube-annealer are available to the recipe.

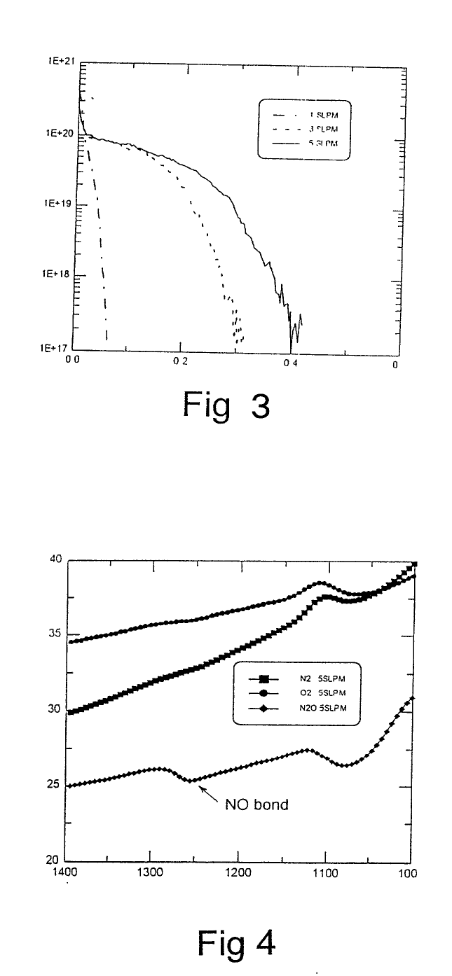

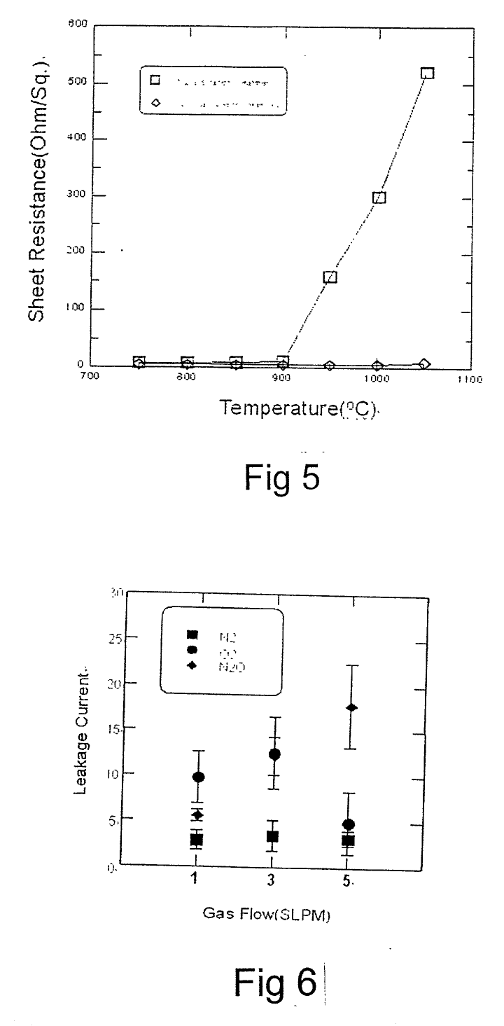

Therefore, the present invention provides a high efficiency diffusion recipe in processing silicon, in which N₂O is taken as environment gas of diffusion, the produced NO complexes strengthen NOED effect more obviously ( see FIG. 3 ), and N₂O used in silicon semiconductor could produce SiN₂O, which is not found during using N₂,O₂ that is proved by experiment ( see FIG. 4 ). Element metal interface obtained by heat treatment process at atmosphere of N₂O has high reliability ( see FIG. 5 ). It can improve the efficiency and output in making semiconductor elements without harm to the integrated circuit ( see FIG. 6 ).

In accordance with the above-mentioned, the present invention not only will not influence the original efficiency but also possessing more applicable value, for which the above4-said viewpoint is further discussed as follows:

The present invention takes N₂O to change environment and get the purpose of fast diffusing impurities. It can save processing time and 8 times interface depths at same long time.

The present invention strengthens NOED effect by NO complexes and quickens diffusing, and making diffusing more obvious , thus greatly reducing cost of production.

The present invention has no harm in characteristics and reliability of the integrated circuit.

To sum up, the present invention has indeed unprecedented process, and not appear in publication as well as no similar product in market, thus there is no doubt that the present invention is original and unique.

1. A fast difflusion recipe for silicon by NO complexes, comprising charging NO complexes into heat treatment equipment in gas way, which is used to promote impurities diffusion and obtain the efficiency of the present invention.

2. The fast diffusion recipe for silicon by NO complexes as defined in claim 1, in which the heat treatment equipment is tube-furnace or fast tube-annealer.

3. The fast diffusion recipe for silicon by NO complexes as defined in claim 1, in which the fast difflusion process is controlled by flow of NO complexes gas.

4. The fast difflusion recipe for silicon by NO complexes as defined in claim 1, in which the impurities is B, As or P.
